(19) United States
(12) Patent Application Publication
(10) Pub. No.: US 2025/0309008 A1
(43) Pub. Date: Oct. 2, 2025

(54) SOLDER THERMAL INTERFACE CORE ATTACHED WITH LOW-TEMPERATURE SOLDER PASTE FOR MICROELECTRONIC DEVICES

(71) Applicant: Intel Corporation, Santa Clara, CA (US)

(72) Inventors: Sergio Antonio CHAN ARGUEDAS, Chandler, AZ (US); Nrup Laljibhai BALAR, Chandler, AZ (US); Kristen MILLER, Phoenix, AZ (US); Elah BOZORG-GRAYELI, Tempe, AZ (US); Peng LI, Chandler, AZ (US)

(21) Appl. No.: 18/619,762

(22) Filed: Mar. 28, 2024

(51) Int. Cl. H01L 23/053; H01L 23/00

(52) U.S. Cl. CPC H01L 23/053; H01L 24/29; H01L 24/32; H01L 24/83; H01L 2224/29109; H01L 2224/29575; H01L 2224/32225; H01L 2224/32503; H01L 2224/83815; H01L 2924/16235; H01L 2924/16251; H01L 2924/2064

(57) ABSTRACT

An integrated circuit package may include a die and a lid over the die. An solder preform core is between the die and the lid. A first intermetallic layer (IML) is between the die and the solder preform and a second intermetallic layer (IML) is between the lid and the solder preform, wherein the first IML and the second IML comprise low-temperature solder (LTS) material.

### BACKGROUND

Today's consumer electronics market frequently demands complex functions requiring very intricate circuitry. Scaling to smaller and smaller fundamental building blocks, e.g. transistors, has enabled the incorporation of even more intricate circuitry on a single die with each progressive generation. Integrated circuit (IC) packages are used for protecting an IC chip or die, and also to provide the die with an electrical interface to external circuitry. With the increasing demand for smaller electronic devices, semiconductor packages are designed to be even more compact and must support larger circuit density, which in some cases may affect solder joint reliability.

For example, some IC packages include one or more die covered by a lid, and the lid is attached to the die by a think solder joint comprising a solder thermal interface material (STIM). The STIM comprises a solder preform between a pair of intermetallic layers (IMLs), where the IMLs are formed during an STIM lid attach process.

The conventional STIM lid attach process applies a flux material to the lid and die or to a solder preform, joins the solder preform to the die or lid, and then places the lid over the die. A reflow process is used to melt the solder preform. During the reflow process, the flux interacts with metals on the lid and the die and with the solder preform to form the IMLs, resulting in a thick solder joint over a large area of the lid. The entire solder preform is melted during this process even though the IMLs are only formed at the interfaces of the die and solder preform and interface of the lid and the solder preform. This process has an inherent tendency to form voids in the IMLs or the bulk of STIM due to both volatiles released from flux when the solder preform is melted, and a non-homogeneous contour match between the solder preform and the lid and die. The voids in either the IMLs or STIM bulk can negatively impact the thermal performance of the packaged ICs.

Proposed solutions include the use of a fluxless formic acid reflow and/or the use of a polymer TIM. However, the use of the fluxless formic acid reflow is expensive and leads to a complex process due to safety concerns during the reflow process. The use of the polymer TIM results in lower thermal performance, and a very thin bond line thickness (BLT) has to be maintained, resulting in a very narrow process margin.

### BRIEF DESCRIPTION OF THE DRAWINGS

FIG. 1A illustrates a cross-sectional view taken along a gate “width” of a conventional thin film integrated circuit structure.

FIG. 1B illustrates a scanning electron microscope (SEM) cross-section view image showing a portion of the IML between the lid and the reflowed solder preform after the STIM lid attach process.

FIG. 1C illustrates a XRAY topside scan of the IC package after the STIM lid attach process showing the inherent voids resulting from the process.

FIG. 2 is a side, cross-sectional view of an example microelectronic or integrated circuit (IC) package in accordance with the disclosed embodiments.

FIG. 3A illustrates a simple process diagram showing an improved STIM lid attach process for fabricating an IC package in accordance with the disclosed embodiments.

FIG. 3B illustrates a simple process diagram showing a specific example of the LTS-STIM lid attach fabrication process.

FIG. 3C illustrates a scanning electron microscope (SEM) cross-section view image showing a portion of the IML between a lid and a solder preform core after the LTS-STIM lid attach process of the disclosed embodiments.

FIG. 3D illustrates an XRAY topside scan of the IC package after the STIM lid attach process showing the absence of voids resulting from the disclosed embodiments.

FIG. 3E illustrates a graph characterizing the junction thermal performance of the IC package fabricated using the LTS-STIM lid attach process of the disclosed embodiments.

FIG. 4 is a cross-sectional side view of an integrated circuit (IC) device assembly that may include an IC package having an unmelted solder thermal interface material with a low-temperature solder paste for improving solder joint reliability,

FIG. 5 illustrates a computing device in accordance with one implementation of the disclosure.

### DESCRIPTION OF THE EMBODIMENTS

Structures and architectures for fabricating IC packages using a solder thermal interface material (STIM) core attached with a low-temperature solder paste for microelectronic devices are described. In the following description, numerous specific details are set forth, such as specific material and tooling regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import. For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The drawings are not necessarily to scale. Although many of the drawings illustrate rectilinear structures with flat walls and right-angle corners, this is simply for ease of illustration, and actual devices made using these techniques will exhibit rounded corners, surface roughness, and other features. The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, the terms “package,” “IC package,” and “microelectronic packages” are synonymous.

One or more embodiments described herein are directed to structures and architectures for fabricating IC packages using a solder thermal interface material (STIM) core attached with a low-temperature solder paste to produce intermetallic layers having an absence of voids that can negatively affect thermal performance. An intermetallic layer (IML) refers to the layer or layers of intermetallic compounds (IMCs) that form at the interface between two dissimilar metallic materials during a high-temperature process, such as soldering, brazing, or thermal compression bonding.

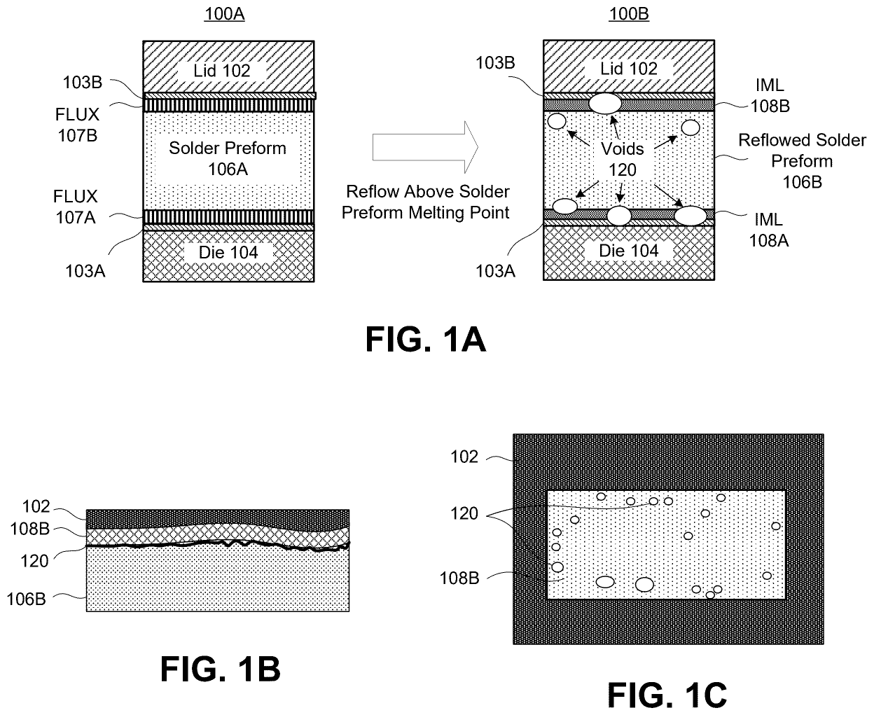

To provide context, FIG. 1A illustrates a simple process diagram showing an example direct STIM lid-attach process for fabricating an IC package. The left-hand side of FIG. 1A illustrates that at one stage during fabrication, IC package 100A includes a die 104 covered by a lid 102 (i.e., an integrated heat spreader (IHS).

A backside surface of the die 104 may include a layer of intermediate material 103A, and an underside surface of the lid 102 may include a layer of intermediate material 103B. Intermediate material 103A and 103B may be any suitable material that mitigates diffusion of exterior material of the lid 102 or the die 104 at the interface with a solder preform 106A. Prior to attaching the lid 102 to the die 104 with the solder preform 106A, a typical STIM lid-attach process includes a flux layer 107A between intermediate material 103A and a solder preform 106A, and another flux layer 107B between intermediate material 103B and the solder preform 106A. In the context of integrated circuit (IC) packaging, flux is a chemical compound used in the soldering process to facilitate the formation of a reliable solder joint between the die and the lid. Flux layers 107A and 107B are collectively referred to as flux 107. A solder preform refers to a pre-formed piece of solder alloy that is used to attach the lid to the die or to attach electronic components, such as integrated circuits (ICs), to a circuit board. The solder preform 106A simplifies the manufacturing process by providing a consistent amount of solder material for a connection. Solder preform 106A helps to improve the quality of the solder joint by ensuring that the solder is evenly distributed.

Referring to the right-hand sides of FIG. 1A, a reflow soldering process is illustrated in which package stack 100A is placed in a reflow oven at a temperature above the melting temperature of the solder preform 106A, which melts the solder alloy in the solder preform 106A and causes the flux 107 to become activated. The flux 107 improves the wetting of the molten solder to allow the solder alloy to flow. The flux interacts with metals on the lid 102 and the die 104 and with the solder alloy in the solder preform. These interactions results in the formation of intermetallic layers (IMLs) 108A and 108B (collectively referred to as IML 108) on each side of reflowed solder preform 106B. This process results in a package stack 100B having a thick solder joint (e.g., 200 μm thick and above) over a large area of the lid (e.g., 400 mm² and above).

The indicator of a good solder joint is the formation of a thin, continuous, and homogenous IML. However, one issue with the STIM lid attach processes is that the entire reflowed solder preform 106B is melted during this process even though the IMLs 108 are only formed at the interfaces between the solder preform 106A and the lid 102 and the die 104. Consequently, the process can result in excessive formation of IML at the solder/substrate interfaces, which can weaken the mechanical properties of the solder joint due to the brittle nature of the IML and different coefficients of thermal expansion of the lid 102 or die 104 and the flux 107. In addition, the use of flux 107 and reflowed solder preform 106B has an inherent tendency to form voids 120 due to volatiles released from flux 107 while the solder is in a liquid state in addition to a non-homogeneous contour match between die 104, solder preform 106A, and the lid 102.

FIG. 1B illustrates a scanning electron microscope (SEM) cross-section view image showing a portion of the IML 108B between the lid 102 and the reflowed solder preform 106B after the STIM lid attach process. The STIM lid attach process results in the formation of the IML 108B that includes one more voids 120 or air gaps (which appear as cracks in cross-section) formed along the interface with the reflowed solder preform 106B.

FIG. 1C illustrates a XRAY topside scan of the IC package 100B after the STIM lid attach process showing the voids 120 formed in the IML 108 and/or the solder preform 106. Both IMLs 108A and 108B can include voids 120 ranging from approximately 1-400 μm in diameter depending on the reflowed solder preform 106B and IML 108 size.

In accordance with one or more embodiments described herein, architectures and methods for fabricating IC packages using an solder thermal interface material (STIM) core attached with a low-temperature solder paste are provided. An improved STIM lid attach process is disclosed in which a low-temperature solder (LTS) paste is used instead of flux. The LTS paste is applied to both the lid/integrated heat spreader (IHS) and the die to solder the die and the lid to a solder preform. A low-temperature reflow process is then used to melt and reflow only the LTS paste at temperatures (e.g., below 150° C.), which is lower than both the melting point of the solder preform and traditional solder pastes. The low-temperature reflow process forms two separate solder joints that connect the die and the lid to the non-melted solder preform, which allows for the controlled formation of the IML at the two interfaces. The LTS-STIM lid attach process of the disclosed embodiments results in a thin, continuous, and homogenous IML that has an absence of voids that can negatively affect thermal performance. Applications of such systems may include but are not limited to, IC or microelectronic packages with improved thermal properties.

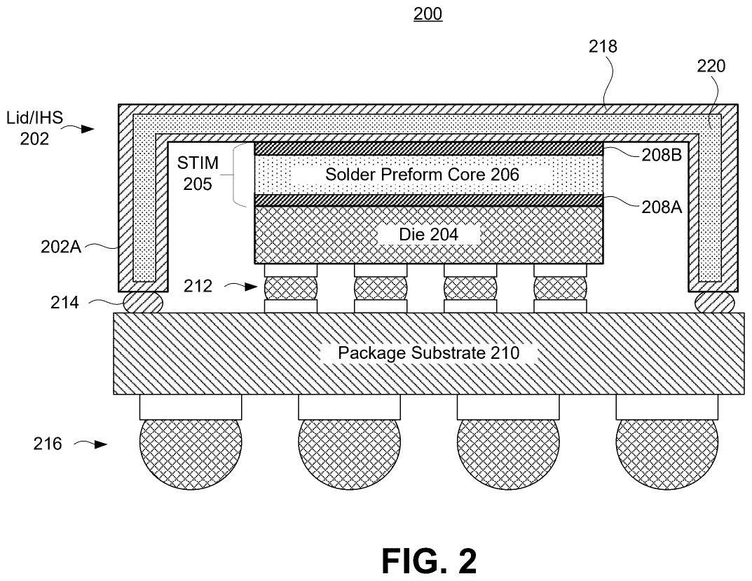

FIG. 2 is a side, cross-sectional view of an example microelectronic or integrated circuit (IC) package in accordance with the disclosed embodiments. The IC package 200 includes a die 204 and a lid 202 over a backside of die 204. A solder joint comprising a solder thermal interface material (STIM) 205 provides a non-adhesive interconnect between the die 204 and the lid 202 for uniform thermal dissipation. During operation of the die 204, the STIM 205 may transfer heat generated by the die 204 to the lid 202. The lid 202 may also be referred to as an integrated heat spreader (IHS).

According to one aspect of the disclosed embodiments, STIM 205 comprises a solder preform core 206 over a first intermetallic layer (IML) 208A and a second IML 208B over the solder preform core 206, which is unmelted during the lid attach process. The IML 208A is between the die 204 and the solder preform core 206, and the second IML 208B is between the lid 202 and the unmelted solder preform core 206. IML 208A and 208B are collectively referred to herein as IML 208.

The solder preform core 206 (also referred to herein as solder preform 206) refers to a pre-formed piece of solder alloy that is used to attach the lid to the die or to attach integrated circuits (ICs) to a circuit board. The solder preform 206 may include any suitable solder material. Because the solder preform no longer needs to be melted, it is possible to utilize higher melting point materials with higher thermal conductivity than indium and Ag/Au/Cu-based alloys or diamond composites. Many potential material combinations exist, but in example embodiments, the solder preform 206 comprises indium. For example, solder preform 206 may comprise pure indium solder or an indium alloy solder (e.g., an indium-tin (In—Sn) or an indium-silver (In—Ag) alloy solder). Other examples could include an indium-gold (In—Au) alloy solder, or an indium-aluminum (In—Al) alloy solder. The solder preform 206 may have a melting greater than 150° C.

According to another aspect of the disclosed embodiments, the IML 208 comprises a low-temperature solder (LTS) material, and flux is not directly used in the lid attach process or the formation of the IML 208. IML 208 is a substance formed when the LTS material comes in contact with other metals on the surface of the die 204 or the lid 202 when the LTS is reflowed or melted (i.e., transitioned from a solid state to a liquid state). When the LTS material is re-solidified, a solder joint is established, where the IML 208 comprises multiple constituents from the LTS material and the other metal on the surface of the lid 202 and die 204. Although flux is not directly used in the lid attach process, those with skill in the art will recognize that LTS material may include solder spheres mixed with some amount of flux. Therefore there may be trace amounts of flux material remaining in the disclosed process, but only as a sub-product of the LTS paste.

In embodiments, LTS material may comprises lead-free solder alloys designed to melt and reflow at lower temperatures compared to traditional tin-lead (SnPb) solders. The IML 208 may comprise combinations of tin (Sn), bismuth (Bi), indium (In), copper (Cu), nickel (Ni) and silver (Ag), but not lead (Pb). Specific examples of compositions may comprise: Sn—Bi alloys e.g., Sn-58Bi, Sn57Bi1Ag); In—Sn alloys, e.g., In-48Sn, and In—Ag alloys, e.g., In-3Ag; and Sn—Bi—Cu—Ni alloys.

The solder joint resulting from the use of an LTS solder material, rather than flux, and the use of the solder preform core 206 that is unmelted results in the formation of a thin, continuous, and homogenous IML 208 that has an absence of voids that would negatively impact the thermal performance of the IC package 200.

The IC package 200 may further include a package substrate 210 to which a front side of the die 204 is coupled via interconnects 212 (which may be, for example, first-level interconnects). The lid 202 may include leg portions 202A that extend towards the package substrate 210, and a sealant 214 (e.g., a polymer-based adhesive) may attach the leg portions 202A of the lid 202 to the top surface of the package substrate 210. The IC package 200 may also include interconnects 216, which may be used to couple the IC package 200 to another component (not shown), such as a circuit board (e.g., a motherboard), an interposer, or another IC package, as known in the art. The interconnects 216 may, in some embodiments, be any suitable second-level interconnects known in the art.

The die 204 may include circuitry to perform any desired functionality. For example, the die 204 may be a logic die (e.g., silicon-based dies), a memory die (e.g., high bandwidth memory), or may include a combination of logic and memory. In some embodiments, the IC package 200 includes multiple dies 204 and the IC package 200 may be referred to as a multi-chip package (MCP). IC package 200 may include passive components not shown for ease of illustration, such as surface-mount resistors, capacitors, and inductors (e.g., coupled to the top or bottom surface of the package substrate 210). More generally, IC package 200 may include any active or passive components known in the art.

The lid 202 may include an exterior material 218 and a core material 220. For example, in some embodiments, the core material 220 may be copper and the exterior material 218 may be nickel (e.g., the copper may be plated with a layer of nickel having a thickness between 5 microns and 10 microns). In another example, the core material 220 may be aluminum and the exterior material 218 may be nickel (e.g., the aluminum may be plated with a layer of nickel having a thickness between 5 microns and 10 microns). In some embodiments, the exterior material 218 and the core material 220 may be the same.

The package substrate 210 may be coupled to the die 204 by the interconnects 212, which may include conductive contacts that are coupled to conductive pathways (not shown) through the package substrate 210, allowing circuitry within the die 204 to electrically couple to the interconnects 216 (or to other devices included in the package substrate 210, not shown). As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket). The interconnects 212 illustrated in FIG. 2 include solder bumps, but interconnects 212 may take any suitable form (e.g., wirebonds, a waveguide, etc.). Similarly, the interconnects 216 may include solder balls (e.g., for a ball grid array (BGA) arrangement), pins in a pin grid array (PGA) arrangement, or lands in a land grid array (LGA) arrangement). Further, although the IC package 200 includes die 204 coupled directly to a package substrate 210, in other embodiments, an intermediate component may be disposed between the die 204 and the package substrate 210 (e.g., a silicon bridge, an organic bridge, and the like).

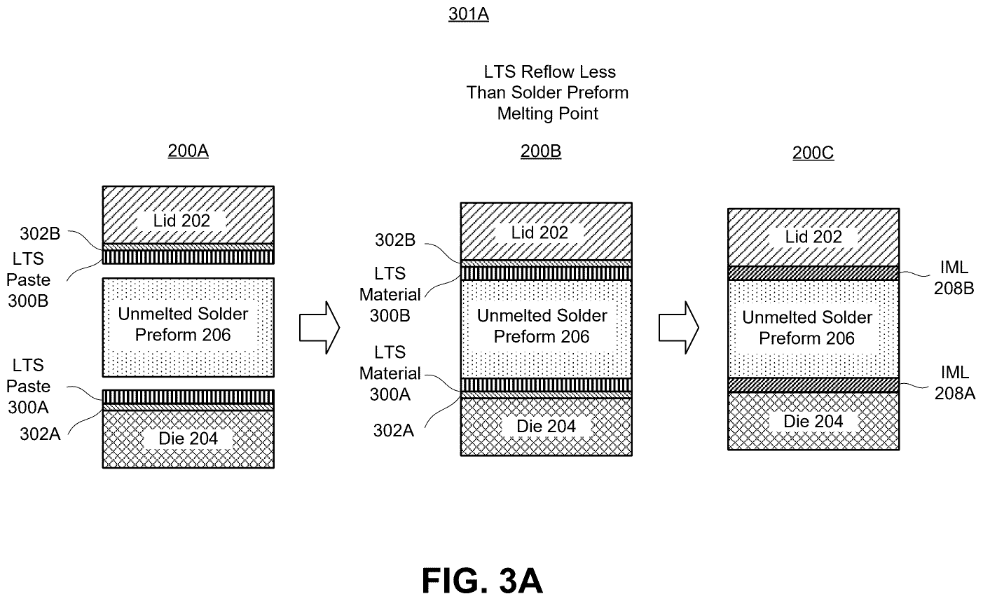

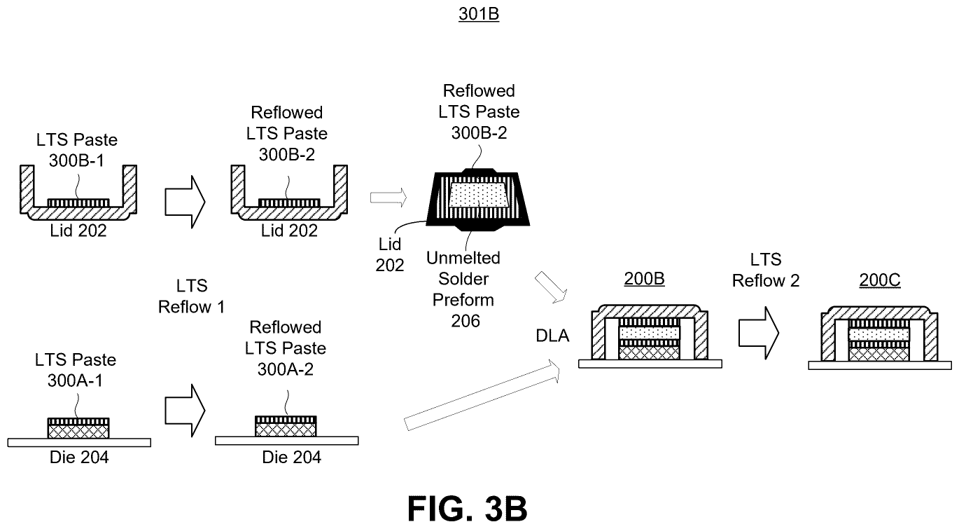

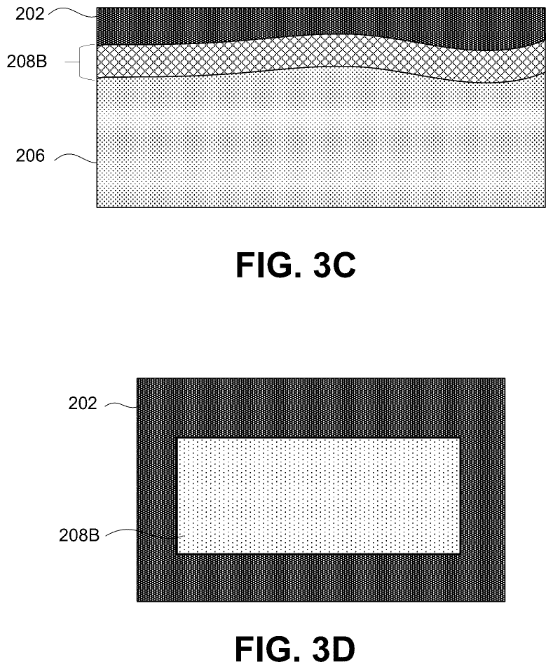

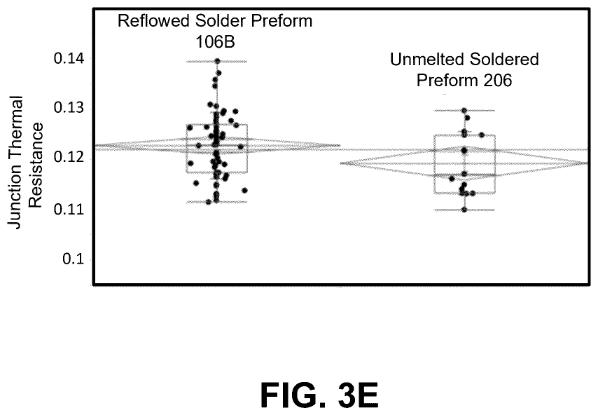

FIG. 3A illustrates a simple process diagram showing an improved STIM lid attach process for fabricating an IC package in accordance with the disclosed embodiments, where like components from FIG. 2 have like reference numerals. The improved STIM lid attach process 301A utilizes a low-temperature solder (LTS) material instead of flux, and a low-temperature reflow that melts only the LTS material and not the solder preform. Therefore, the improved process is referred to as an LTS-STIM lid attach.

Referring to the left-hand side of FIG. 3A, the process may begin with unassembled package stack 200A comprising the lid 202, the die 204, and solder preform core 206. A backside surface of the die 204 may include a layer of intermediate material 302A, and an underside surface of the lid 202 may include a layer of intermediate material 302B. Intermediate material 302A and 302B are collectively referred to as intermediate material 302. The intermediate material 302 may include any suitable material that adequately mitigates diffusion of exterior material of the lid 202 or the die 204 into the IML 208 at the interface with the solder preform core 206. The thickness of the intermediate material 302 may take any suitable value (e.g., between 70 nm and 7 μm).

In some embodiments, the intermediate material 302 may include gold, vanadium, titanium, bismuth, zirconium, tungsten, cerium, hafnium, tantalum, yttrium, niobium, or molybdenum. For example, the intermediate material may include vanadium and nickel (e.g., in the form of a nickel vanadium compound), titanium and nitrogen (e.g., in the form of titanium nitride), titanium and oxygen (e.g., in the form of titanium oxide), zirconium and boron (e.g., in the form of zirconium bore ride), zirconium and oxygen (e.g., in the form of zirconium oxide), tungsten and silicon (e.g., in the form of tungsten silicide), tungsten and nitrogen (e.g., in the form of tungsten nitride), cerium and oxygen (e.g., in the form of cerium oxide), hafnium (e.g., pure hafnium), tantalum (e.g., pure tantalum), yttrium (e.g., pure yttrium), niobium (e.g., pure niobium), or molybdenum (e.g., pure molybdenum).

The LTS-STIM lid attach process applies a layer of LTS material 300A over the intermediate material 302A of the die 204 and applies a layer of LTS material 300B over intermediate material 302B on the lid 202. LTS material 300A and LTS material 300B are collectively referred to as LTS material 300. The LTS material 300 may be applied by any suitable method including deposition, dipping, or screen printing. Depending on desired mechanical properties, the LTS material 300 may be applied to a thickness ranging from approximately 1-100 microns.

Referring to the middle of FIG. 3A, a package stack 200B is assembled by placing solder preform 206 over the LTS material 300A on the die 204 and aligning and placing the lid 202 with LTS material 300B over the die 204. Alternatively, package stack 200B can be assembled by placing the solder preform 206 on LTS material 300B of the lid 202, and then placing the lid 202 with LTS material 300B on the die 204 (FIG. 3B).

After assembly, package stack 200B is placed in a reflow oven or exposed to other heating sources like infrared lamps, and an LTS reflow process is performed at a temperature less than the melting point of the solder preform 206. As the temperature rises, the LTS material 300 melts and flows, forming solder joints. After reaching the peak temperature, the package stack 200B is cooled down, causing the solder to solidify and harden. According to disclosed embodiments, the LTS reflow process melts only the LTS material 300, leaving solder preform 206 unmelted.

The LTS reflow temperature and the melting point of the LTS material 300 are lower than both the melting point of the solder preform and traditional solder materials. For example, in some embodiments, the LTS reflow temperature and the melting point of the LTS material 300 are less than 150° C. In specific embodiments, the LTS reflow temperature and the melting point of the LTS material 300 may range from approximately 130-150° C.

Referring to the right-hand side of FIG. 3A, package stack 200C is shown after completion of the LTS-STIM lid attach process. The LTS reflow produced in a package stack 200C that includes die 204, IML 208A over the die 204, solder preform core 206 over the IML 208A, IML 208B over the solder preform 206, and the lid 202 over the IML 208B.

The IML 208 comprising reflowed LTS material forms two separate solder joints, where IML 208A joins the die 204 to the solder preform core 206 and IML 208B joins the lid 202 to the non-melted solder preform 206, which allows for the controlled formation of IML 208 at the two interfaces.

By avoiding the need to completely melt the solder preform 206, the preform reflow process is eliminated or significantly shortened, thus reducing the energy consumption and improving the cycle time of production. Additionally, the IML 208 can be improved by locally modifying the metallurgy at the solder joint using intermediate material 302. The LTS-STIM lid attach process of the disclosed embodiments results in a thin, continuous, and homogenous IML 208.

FIG. 3B illustrates a simple process diagram showing a specific example of the LTS-STIM lid attach fabrication process. This example embodiment poses one way of fabricating the IC package 200, where like components from FIG. 3A have like reference numerals. STIM lid attach fabrication process 301B comprises a dual flow process that may be performed in parallel or sequentially. The LTS-STIM lid attach begins by dispensing LTS material 300B-1 on the underside of the lid 202 and dispensing LTS material 300A-1 on the backside of the die 204. In one embodiment, LTS material 300B-1 may be dispensed adjacent to the lid periphery or in a specific area of the underside of the lid 202. As described in FIG. 3A, the lid 202 and the die 204 may include an intermediate material 302.

In this example, the LTS material 300B-1 may comprise L27, which is an alloy comprising Sn, Bi, Cu, and Ni and has a melting point of approximately 130° C.

The LTS-STIM lid attach proceeds by performing a first LTS reflow process on the lid 202 and performing a first reflow process on the die 204, resulting in reflowed LTS material 300B-2 on the lid 202 and 300A-2 on the die 204.

The solder preform core 206 is then applied to the underside of the lid 202 (shown in an angled perspective view of the lid) on the reflowed LTS material 300B-2. In the example shown, the solder preform core 206 is placed in the center of the underside of the lid 202 and is not coextensive with reflowed LTS material 300B-2. In other embodiments, the solder preform core 206 may be coextensive with reflowed LTS material 300B-2.

A direct lid attach (DLA) process is then performed in which the lid 202 may be flipped over, aligned, and placed on the die 204, forming package stack 200B. A second LTS reflow process is performed by placing the package stack 200B in a reflow oven or exposing the package stack 200B to other heating sources. The reflow is performed at a temperature less than the melting point of the solder preform core 206, resulting in package stack 200C. This leads to the formation of Au—Sn—Bi IML at the interface with both die 204 and lid 202. Any solvent residue is then cleaned from the IML surface.

Rather than performing a second reflow, the DLA process may be performed by thermal compressive bonding where a controlled pressure and temperature are applied to the package stack 200B at a temperature less than the melting point of the solder preform core 206. The thermal compressive bonding method does not involve melting the solder preform 206 but relies on the formation of the IML through solid-state diffusion at elevated temperatures and pressures.

FIG. 3C illustrates a scanning electron microscope (SEM) cross-section view image showing a portion of the IML 208B between the lid 202 and the solder preform core 206 after the LTS-STIM lid attach process of the disclosed embodiments. The LTS-STIM lid attach process results in the formation of the IML 208B solder joint at the interface with the lid 202. In this example, IML 208B comprises reflowed LTS material mixed with nickel, gold, and indium as a result of the interaction with the intermediate material 302B. Flux material is not present.

FIG. 3D illustrates an XRAY topside scan of the IC package after the STIM lid attach process showing the IML 208B at the interface with the lid 202. As depicted in both FIGS. 3C and 3D, IML 208, in addition to the bulk of the preform, has an absence of voids that can negatively affect the thermal performance of the IC package 200. Due to the materials that may be present in the IML (e.g., Sn, Bi, and Au) and their inherent properties, there may be some microvoids in IML 208, but on a scale that would not negatively affect the thermal performance of the IC package. For example, the size of the microvoids is less than 40 μm in diameter. In one embodiment, the microvoids may range from approximately 10-20 μm in diameter, depending on the thickness of the LTS solder material.

FIG. 3E illustrates a graph characterizing the junction thermal performance of the IC package fabricated using the LTS-STIM lid attach process of the disclosed embodiments. An IC package is measured by junction thermal resistance, which is the inverse of thermal conductivity through the IC package. The phrase “junction thermal resistance” refers to the resistance to heat flow from a semiconductor junction (the active region where electronic operations occur) to the lid.

The left-hand side of the graph shows the standard deviation of the junction thermal resistance of reflowed/melted solder preform 106B, and the right-hand side of the graph shows the standard deviation of the junction thermal resistance of the solder preform core 206, both measured at various locations around the center of the lid. A lower junction thermal resistance is desirable, as it means that heat can be more effectively transferred from the junction to the package exterior, allowing for better heat dissipation and lower junction temperatures. As depicted, the solder preform core 206 generally has lower junction temperatures than the reflowed solder preform 106B.

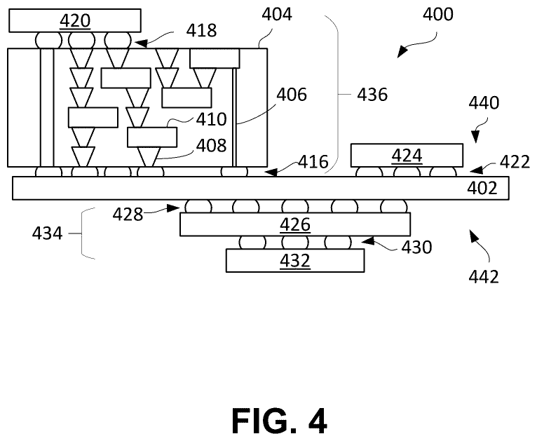

FIG. 4 is a cross-sectional side view of an integrated circuit (IC) device assembly that may include an IC package having an unmelted solder thermal interface material with a low-temperature solder paste for improving solder joint reliability, in accordance with one or more of the embodiments disclosed herein.

Referring to FIG. 4, an IC device assembly 400 includes components having one or more integrated circuit structures described herein. The IC device assembly 400 includes a number of components disposed on a circuit board 402 (which may be, e.g., a motherboard). The IC device assembly 400 includes components disposed on a first face 440 of the circuit board 402 and an opposing second face 442 of the circuit board 402. Generally, components may be disposed on one or both faces 440 and 442. In particular, any suitable ones of the components of the IC device assembly 400 may include a number of RF filters fabricated on a semiconductor package using selective seeding, such as disclosed herein.

In some embodiments, the circuit board 402 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 402. In other embodiments, the circuit board 402 may be a non-PCB substrate.

The IC device assembly 400 illustrated in FIG. 4 includes a package-on-interposer structure 436 coupled to the first face 440 of the circuit board 402 by coupling components 416. The coupling components 416 may electrically and mechanically couple the package-on-interposer structure 436 to the circuit board 402, and may include solder balls (as shown in FIG. 4), male and female portions of a socket, an adhesive, an underfill material, and/or any other suitable electrical and/or mechanical coupling structure.

The package-on-interposer structure 436 may include an IC package 420 coupled to an interposer 404 by coupling components 418. The coupling components 418 may take any suitable form for the application, such as the forms discussed above with reference to the coupling components 416. Although a single IC package 420 is shown in FIG. 4, multiple IC packages may be coupled to the interposer 404. It is to be appreciated that additional interposers may be coupled to the interposer 404. The interposer 404 may provide an intervening substrate used to bridge the circuit board 402 and the IC package 420. The IC package 420 may be or include, for example, a die or any other suitable component. Generally, the interposer 404 may spread a connection to a wider pitch or reroute a connection to a different connection. For example, the interposer 404 may couple the IC package 420 (e.g., a die) to a ball grid array (BGA) of the coupling components 416 for coupling to the circuit board 402. In the embodiment illustrated in FIG. 4, the IC package 420 and the circuit board 402 are attached to opposing sides of the interposer 404. In other embodiments, the IC package 420 and the circuit board 402 may be attached to a same side of the interposer 404. In some embodiments, three or more components may be interconnected by way of the interposer 404.

The interposer 404 may be formed of an epoxy resin, a fiberglass-reinforced epoxy resin, a ceramic material, or a polymer material such as polyimide. In some implementations, the interposer 404 may be formed of alternate rigid or flexible materials that may include the same materials described above for use in a semiconductor substrate, such as silicon, germanium, and other group III-V and group IV materials. The interposer 404 may include metal interconnects 410 and vias 408, including but not limited to through-silicon vias (TSVs) 406. The interposer 404 may further include embedded devices, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio-frequency (RF) devices, power amplifiers, power management devices, antennas, arrays, sensors, and microelectromechanical systems (MEMS) devices may also be formed on the interposer 404. The package-on-interposer structure 436 may take the form of any of the package-on-interposer structures known in the art.

The IC device assembly 400 may include an IC package 424 coupled to the first face 440 of the circuit board 402 by coupling components 422. The coupling components 422 may take the form of any of the embodiments discussed above with reference to the coupling components 416, and the IC package 424 may take the form of any of the embodiments discussed above with reference to the IC package 420.

The IC device assembly 400 illustrated in FIG. 4 includes a package-on-package structure 434 coupled to the second face 442 of the circuit board 402 by coupling components 428. The package-on-package structure 434 may include an IC package 426 and an IC package 432 coupled together by coupling components 430 such that the IC package 426 is disposed between the circuit board 402 and the IC package 432. The coupling components 428 and 430 may take the form of any of the embodiments of the coupling components 416 discussed above, and the IC packages 426 and 432 may take the form of any of the embodiments of the IC package 420 discussed above. The package-on-package structure 434 may be configured in accordance with any of the package-on-package structures known in the art.

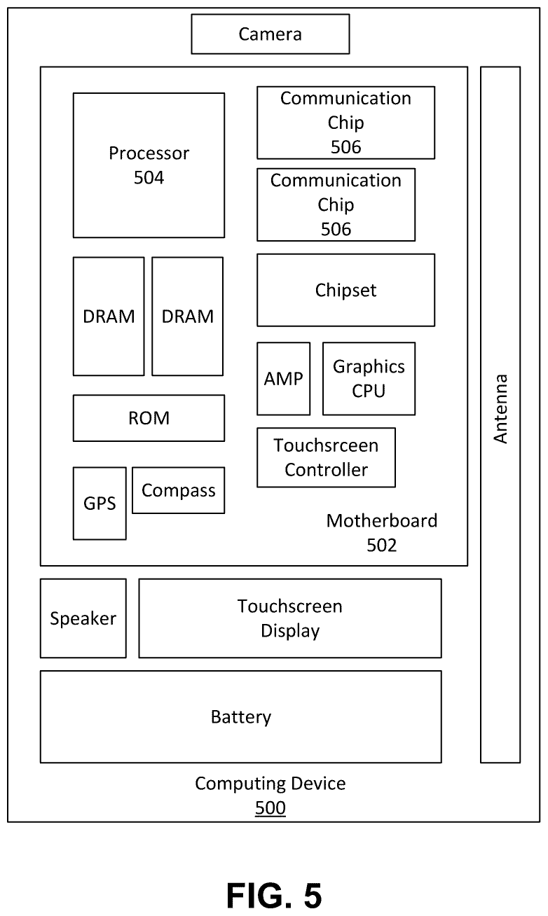

FIG. 5 illustrates a computing device 500 in accordance with one implementation of the disclosure. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

Depending on its applications, computing device 500 may include other components that may or may not be physically and electrically coupled to the board 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the disclosure, the integrated circuit die of the processor includes an IC package having an unmelted solder thermal interface material with a low-temperature solder paste for improving solder joint reliability, in accordance with implementations of embodiments of the disclosure. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of embodiments of the disclosure, the integrated circuit die of the communication chip includes an IC package having an unmelted solder thermal interface material with a low-temperature solder paste for improving solder joint reliability, in accordance with implementations of embodiments of the disclosure.

In further implementations, another component housed within the computing device 500 may contain an integrated circuit die that includes an IC package having an unmelted solder thermal interface material with a low-temperature solder paste for improving solder joint reliability, in accordance with implementations of embodiments of the disclosure.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

Thus, embodiments described herein include an IC package having an unmelted solder thermal interface material with a low-temperature solder paste to improve sold or joint reliability in semiconductor packages.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Embodiment 1. An apparatus, comprising: a die; a lid over the die; a solder preform core between the die and the lid; a first intermetallic layer (IML) between the die and the solder preform; and a second IML between the lid and the solder preform, wherein the first IML and the second IML comprise low-temperature solder (LTS) material.

Embodiment 2. The apparatus of Embodiment 1, wherein the LTS solder material comprises combinations of tin (Sn), bismuth (Bi), indium (In), copper (Cu), nickel (Ni) and silver (Ag).

Embodiment 3. The apparatus of Embodiment 1 or 2, wherein the LTS solder material comprises Sn—Bi alloys, In—Sn alloys, In—Ag alloys, or Sn—Bi—Cu—Ni alloys.

Embodiment 4. The apparatus of Embodiment 1, 2, or 3, wherein the LTS material has a thickness ranging from approximately 1-100 microns.

Embodiment 5. The apparatus of Embodiment 1, 2, 3, or 4, wherein the LTS material has a melting point less than a melting point of the solder preform core.

Embodiment 6. The apparatus of Embodiment 1, 2, 3, 4, or 5, wherein the LTS material has a melting point less than 150° C.

Embodiment 7. The apparatus of Embodiment 6, wherein the LTS material has a melting point ranging from approximately 130-150° C.

Embodiment 8. The apparatus of Embodiment 1, 2, 3, 4, 5, 6, or 7, wherein the solder preform core has a melting point greater than 150° C.

Embodiment 9. The apparatus of Embodiment 1, 2, 3, 4, 5, 6, 7, or 8, wherein the solder preform core comprises combinations of indium (In), tin (Sn), silver (Ag), and lead (Pb).

Embodiment 10. The apparatus of Embodiment 1, 2, 3, 4, 5, 6, 7, 8, or 9, wherein the solder preform core comprises a pure indium solder.

Embodiment 11. The apparatus of Embodiment 1, 2, 3, 4, 5, 6, 7, 8, 9, or 10, wherein the solder preform core comprises an indium alloy.

Embodiment 12. An apparatus, comprising: a package substrate; a die, a front side of the die coupled to the package substrate; a first intermetallic Layer (IML) over a backside of the die; an solder preform core over the first IML; a second IML over the solder preform core; and a lid over the second IML, wherein the first IML and the second IML comprise combinations of tin (Sn), bismuth (Bi), indium (In), copper (Cu), nickel (Ni), and silver (Ag).

Embodiment 13. The apparatus of Embodiment 12, wherein the first IML and the second IML have an absence of voids that negatively affect thermal performance of the IC package.

Embodiment 14. The apparatus of Embodiment 12 or 13, wherein the first IML and the second IML comprise low-temperature solder (LTS) material.

Embodiment 15. The apparatus of Embodiment 14, wherein the LTS solder material comprises Sn—Bi alloys, In—Sn alloys, In—Ag alloys, or Sn—Bi—Cu—Ni alloys.

Embodiment 16. The apparatus of Embodiment 14 or 15, wherein the LTS material has a melting point less than a melting point of the solder preform core.

Embodiment 17. The apparatus of Embodiment 14, 15, or 16, wherein the LTS material has a melting point ranging from approximately 130-150° C.

Embodiment 18. A method of fabricating an apparatus, comprising: applying a first layer of low-temperature solder (LTS) material over a die; applying a second layer of LTS solder material over a lid; assembling a package stack by placing a solder preform on the first LTS solder material or on the second layer of LTS material; assembling the package by aligning and placing the lid over the die, and performing a reflow process on the package stack at a temperature less than a melting point of the solder preform such that the reflow process melts only the first LTS material and the second layer of LTS but not the solder preform.

Embodiment 19. The method of Embodiment 18, further comprising producing by the reflow process a first intermetallic layer (IML) between the die and the solder preform, and a second IML between the solder preform and the lid, the first IML and the second IML having an absence of voids.

Embodiment 20. The method of Embodiment 18 or 19, wherein the first IML and the second IML include the LTS low-temperature solder (LTS) material.

What is claimed is:

1. An apparatus, comprising:
a die;
a lid over the die;
a solder preform core between the die and the lid;
a first intermetallic layer (IML) between the die and the solder preform; and
a second IML between the lid and the solder preform, wherein the first IML and the second IML comprise low-temperature solder (LTS) material.

2. The apparatus of claim 1, wherein the LTS solder material comprises combinations of tin (Sn), bismuth (Bi), indium (In), copper (Cu), nickel (Ni) and silver (Ag).

3. The apparatus of claim 1, wherein the LTS solder material comprises Sn—Bi alloys, In—Sn alloys, In—Ag alloys, or Sn—Bi—Cu—Ni alloys.

4. The apparatus of claim 1, wherein the LTS material has a thickness ranging from approximately 1-100 microns.

5. The apparatus of claim 1, wherein the LTS material has a melting point less than a melting point of the solder preform core.

6. The apparatus of claim 1, wherein the LTS material has a melting point less than 150° C.

7. The apparatus of claim 6, wherein the LTS material has a melting point ranging from approximately 130-150° C.

8. The apparatus of claim 1, wherein the solder preform core has a melting point greater than 150° C.

9. The apparatus of claim 1, wherein the solder preform core comprises combinations of indium (In), tin (Sn), silver (Ag), and lead (Pb).

10. The apparatus of claim 1, wherein the solder preform core comprises a pure indium solder.

11. The apparatus of claim 1, wherein the solder preform core comprises an indium alloy.

12. An apparatus, comprising:
a package substrate;
a die, a front side of the die coupled to the package substrate;
a first intermetallic layer (IML) over a backside of the die;
an solder preform core over the first IML;
a second IML over the solder preform core; and
a lid over the second IML, wherein the first IML and the second IML comprise combinations of tin (Sn), bismuth (Bi), indium (In), copper (Cu), nickel (Ni), and silver (Ag).

13. The apparatus of claim 12, wherein the first IML and the second IML have an absence of voids that negatively affect thermal performance of the IC package.

14. The apparatus of claim 12, wherein the first IML and the second IML comprise comprises low-temperature solder (LTS) material.

15. The apparatus of claim 14, wherein the LTS solder material comprises Sn—Bi alloys, In—Sn alloys, In—Ag alloys, or Sn—Bi—Cu—Ni alloys.

16. The apparatus of claim 14, wherein the LTS material has a melting point less than a melting point of the solder preform core.

17. The apparatus of claim 16, wherein the LTS material has a melting point ranging from approximately 130-150° C.

18. A method of fabricating an apparatus, comprising:
applying a first layer of low-temperature solder (LTS) material over a die;
applying a second layer of LTS solder material over a lid;
assembling a package stack by placing a solder preform on the first LTS solder material or on the second layer of LTS material; and
assembling the package by aligning and placing the lid over the die, and performing a reflow process on the package stack at a temperature less than a melting point of the solder preform, such that the reflow process melts only the first LTS material and the second layer of LTS but not the solder preform.

19. The method of claim 18, further comprising producing by the reflow process a first intermetallic layer (IML) between the die and the solder preform, and a second IML between the solder preform and the lid, the first IML and the second IML having an absence of voids.

20. The method of claim 18, wherein the first IML and the second IML include the LTS material.
